(19) United States
(12) Patent Application Publication
(10) Pub. No.: US 2026/0127331 A1
(43) Pub. Date: May 7, 2026

(54) KARST COLLAPSE SUSCEPTIBILITY EVALUATION ANALYSIS METHOD AND SYSTEM BASED ON ANALYTIC HIERARCHY PROCESS

(71) Applicant: China University of Petroleum (East China), Qingdao (CN)

(72) Inventors: Zhongfeng DUAN, Qingdao (CN); Fulai LI, Qingdao (CN); Fangyu DONG, Qingdao (CN); Xiang YU, Qingdao (CN); Jianyang SONG, Qingdao (CN)

(73) Assignee: China University of Petroleum (East China), Qingdao (CN)

(21) Appl. No.: 19/379,665

(22) Filed: Nov. 4, 2025

(30) Foreign Application Priority Data
Mar. 24, 2025 (CN) 202510346196.8

(51) Int. Cl. G06F 30/18

(52) U.S. Cl. CPC G06F 30/18

(57) ABSTRACT

The invention belongs to the field of karst collapse analysis technology. The invention discloses a karst collapse susceptibility evaluation analysis method and system based on analytic hierarchy process, including: marking the measurement points in the karst area, collecting the karst data of the measurement points, standardizing the karst data, and obtaining the standard karst data; performing a geomagnetic division of the measurement points based on the geomagnetic intensity to obtain a hole point set; evaluating the biological activity of the hole point set by soil microbial data, and obtaining the microbial activity index; based on the atmospheric pressure, performing a pressure fluctuation analysis of the hole point set to obtain the pressure fluctuation index; based on the microbial activity index and pressure fluctuation index, constructing the collapse evaluation function. It effectively improves the accuracy of karst collapse analysis.

### TECHNICAL FIELD

The present disclosure relates to the field of karst collapse analysis technology, and specifically, the present disclosure relates to a karst collapse susceptibility evaluation analysis method and system based on analytic hierarchy process.

### BACKGROUND

The patent with an application number of CN118114007A discloses a karst collapse geological monitoring information analysis system, including an information acquisition unit, a regional division unit, a normal analysis unit, an abnormal analysis unit, an information storage unit, an analysis and an early warning unit, and an information output unit. It involves the field of karst collapse information analysis technology, and solves the technical problem that there is no comprehensive past data for objective analysis, and the data obtained from a single aspect has analysis errors. By combining the acquired data with the past data, the error in the analysis process is further reduced. Meanwhile, different areas are divided according to the obtained data, and different methods are adopted to analyze the divided regional data. Secondly, data acquisition and comparison are carried out for abnormal areas to carry out timely early warning analysis of abnormal areas, which can remind relevant staff to respond. At the same time, various data are obtained for analysis, which can ensure the objectivity of the analysis results.

In the field of karst collapse susceptibility evaluation, the current karst collapse evaluation methods usually ignore the relationship between the morphological characteristics of the underground karst pipeline network and geomagnetic anomalies. The existence and morphology of karst pipelines have a direct impact on karst development and collapse. Geomagnetic anomaly is one of the important precursors of karst collapse, since the karst pipelines and underground cavities will affect the distribution of underground magnetic fields and due to the lack of research on the correlation between underground karst pipeline network morphology and geomagnetic anomalies, it is impossible to accurately identify the distribution and changes of underground pipelines in the actual karst collapse evaluation process, resulting in inaccurate evaluation results. Thus, the occurrence of karst collapse cannot be effectively predicted; karst development is also affected by soil microbial community structure. Microorganisms can change the formation environment of karst by chemical reaction and mineral degradation. The existing evaluation methods fail to take into account the influence of microbial communities and ignore the role of this biological factor in karst development, which makes the evaluation model not comprehensive enough and underestimates the risk of karst collapse in some areas, especially in areas where microorganisms are active, which increases the error and inaccuracy of the evaluation results. The fluctuation of atmospheric pressure affects the stability of underground cavities, especially under seasonal or sudden climate change, the pressure fluctuation will have different degrees of influence on the underground structure. The current karst collapse evaluation methods lack the analysis of the coupling mechanism of atmospheric pressure fluctuation, which increases the evaluation error and leads to the failure of effective early warning before the disaster.

In view of this, the invention proposes a karst collapse susceptibility evaluation analysis method and system based on analytic hierarchy process to solve the above problems.

### SUMMARY

In order to overcome the above defects of the existing technology and achieve the above purposes, the present disclosure provides the following technical solutions: a karst collapse susceptibility evaluation analysis method based on analytic hierarchy process, including:
S1, marking a measurement point in a karst area, collecting karst data of the measurement point, standardizing the karst data, and obtaining the standard karst data; the karst data include: geomagnetic intensity, soil microbial data, karst temperature, soil nitrogen and carbon content, atmospheric pressure, and point coordinates;
S2, performing a geomagnetic division of the measurement point based on geomagnetic intensity to obtain a hole point set;
S3, evaluating a biological activity of the hole point set by soil microbial data to obtain a microbial activity index, performing a pressure fluctuation analysis of the hole point set based on the atmospheric pressure to obtain the pressure fluctuation index;
S4, constructing a collapse evaluation function based on microbial activity index and pressure fluctuation index.

In some embodiments, the collection method of karst data includes:
a measurement route and a measurement interval are preset, and the measurement points in the measurement line are marked based on the measurement interval; an initial position of the measurement line is used as an initial measurement point; starting from the initial measurement point, a position of each measurement interval is marked as the measurement point, and a geomagnetic detector, a microbial sensor, a soil micro sensor, a temperature sensor and a pressure sensor are set for each measurement point; the data acquisition of each measurement point is collected in the same time series; the point coordinates are determined based on the karst area, a point in the karst area is selected as a coordinate center point to construct a standard coordinate system; a horizontal axis distance and a vertical axis distance of each measurement point from the coordinate center point constitute the point coordinates.

In some embodiments, the method of geomagnetic division of the measurement point includes:

For karst data, each type of data in the karst data is used as data to be converted; a time scale is preset, and a historical mean of each data to be converted is calculated based on time scale parameters; a recorded time point of the data to be converted is used as a cut-off point; a data to be converted at the same measurement point in the time scale before the cut-off point is selected to form a scale set, and a mean value of the data in the scale set is calculated as a historical mean; a recorded time point of the data to be converted is used as a measurement time, and the data to be converted at the same measurement time is selected to form the time data set; a mean value of the data in the time data set is used as a time mean, and the standard deviation of the data in the time data set is used as a time standard deviation; based on the historical mean, time mean and time standard deviation, the data to be converted are standardized. The formula for standardizing the data to be converted is:

$$Res = arcsinh ( \frac{data - μ}{σ} ) \times exp ( - \frac{\vert data - \overline{d} \vert}{τ} ) ;$$

where Res denotes the standard data, data denotes the data to be converted, μ denotes the mean value of the time, σ denotes the time standard deviation, τ denotes the time scale, d̅ denotes the historical mean, arcsinh( ) denotes an inverse hyperbolic sine function, and all standard data constitute the standard karst data.

In some embodiments, the method for obtaining the microbial activity index includes:

Based on the measurement route, a previous measurement point of the current measurement point is selected as a differential analysis point; a finite difference method is used to analyze the geomagnetic intensity of the current measurement point by the differential analysis point, and the lateral variation factor is obtained. The finite difference method is used to analyze the geomagnetic intensity of the current measurement point by the finite difference method, and the longitudinal variation factor is obtained; a depth scale set is preset and traversed; traversed elements are used as scale factors, and a magnetic field tensor analysis is performed on each scale factor to obtain a geomagnetic depth tensor; a geomagnetic span is preset, the geomagnetic span includes a horizontal axis span and a vertical axis span, a geomagnetic anomaly evaluation of the measurement points is carried out based on the geomagnetic depth tensor to obtain a magnetic anomaly intensity index; a spline analysis method is used to construct a magnetic anomaly fluctuation curve with a scale factor and a corresponding magnetic anomaly intensity index, a maximum point and a minimum point of a extreme value of the magnetic anomaly fluctuation curve are recorded; a difference between the maximum point and the minimum point of the extreme value is used as a hole evaluation index, and a hole evaluation threshold is preset, the measurement points with the hole evaluation index greater than or equal to the hole evaluation threshold are marked as the hole points; the scale factor with the small value of the scale factor corresponding to the maximum point and the minimum point is the start point of the hole, and the other is an end point of the hole; the data of the start point and the end point of the hole are merged into the hole point, and all the hole points constitute the hole point set.

In some embodiments, the formula for evaluating the geomagnetic anomaly of the measurement point is:

$$MAI = {\int }_{y - b}^{y + b} {\int }_{x - a}^{x + a} \vert ∇ B \vert dx dy \times ( 1 + γcos ( wt ) ) ;$$

where MAI denotes a magnetic anomaly intensity index, a denotes a horizontal axis span, b denotes a vertical axis span, x denotes a horizontal axis value of the point coordinate, y denotes a vertical axis value of the point coordinate, dx and dy denote integral operations, γ denotes a period adjustment coefficient, w denotes an angular frequency parameter, and t denotes a time scale.

In some embodiments, the method of analyzing the pressure fluctuation of the hole point set includes:

The statistical analysis method is used to analyze soil microbial data of all measurement points, and a microbial category table is obtained; a microbial category table contains microbial species and the corresponding total number of species; the number of species of each microbial species in the hole point is divided by the total number of species of the corresponding microbial species in the microbial category table as a species richness, and a biodiversity of each measurement point is evaluated based on the species richness to obtain a biodiversity index; the maximum value of the biodiversity index is recorded as a maximum activity index of the area, and the microbial activity of the hole point is carried out based on the maximum activity index of the area; the formula for evaluating the microbial activity of the hole points is:

$$BAI = \frac{Act}{Mliv} \times θ ln ( 1 + \frac{N}{C} ) ;$$

where BAI denotes a microbial activity index, Mliv denotes a maximum activity index, θ denotes an environmental regulation coefficient, N denotes a soil nitrogen content, and C denotes a soil carbon content.

In some embodiments, the formula for biodiversity evaluation at each measurement point is as follows:

$$Act = - sin \frac{π S}{{S}_{max}} \sum ( {E}_{i} \times ln {E}_{i} ) \times exp ( - δ T ) ;$$

where Act denotes a biodiversity index, π denotes a circumference rate, S denotes the microbial species, Sₘₐₓ denotes the total number of microbial species in the microbial category table, Pᵢ denotes a species richness of the i-th microbial species in the hole point, δ denotes a temperature adjustment coefficient, and T denotes a karst temperature.

In some embodiments, the method of analyzing the pressure fluctuation of the hole point set includes:

The hole point in the hole point set is used as a regional center, and the distance scale is preset, the distance scale is used as the regional radius, the regional center is used as the center of the circle, and the regional radius is used as a circle radius to draw the circle to obtain the regional circle; the measurement points contained in the regional circle are used as the pressure evaluation points, and the pressure evaluation points and the pressure center are used as the fluctuation analysis points; for each fluctuation analysis point, the fluctuation analysis point is used as the pressure center to draw a cross line, and the four areas divided by a cross line are used as a selection domain; a distance measurement formula is used to calculate a distance between other fluctuation analysis points and a center of the cross line as an evaluation distance; in each selection domain, the fluctuation analysis point with the smallest evaluation distance is selected as a pressure boundary point, the pressure boundary points in a diagonal area are taken as a group of boundary groups, and the fluctuation analysis points in the center of the cross line are taken as a difference center; a central difference algorithm is used to calculate a pressure fluctuation gradient of each group of boundary groups; a mean value of the pressure fluctuation gradient is used as a fluctuation factor, and the mean value of the fluctuation factor of all the fluctuation analysis points is calculated as the pressure propagation operator; based on the pressure propagation operator, the pressure fluctuation of the hole point is evaluated; the formula for evaluating the pressure fluctuation of the hole point is:

$$PI = {\int }_{low}^{hig} ( SZ \times tan h ( \frac{Δ P}{{P}_{0}} ) ) \times exp ( - ε H ) dH ;$$

where PI denotes a pressure fluctuation index, SZ denotes a pressure fluctuation factor, P₀ denotes a standard atmospheric pressure, ΔP denotes a difference between the atmospheric pressure and the standard atmospheric pressure, ε denotes a fluctuation attenuation coefficient, low denotes a start point of the hole, hig denotes the end point of the hole, and H denotes a depth of the hole.

In some embodiments, the formula of the collapse evaluation function is as follows:

Dang=w₁×BAI+w₂×PI; Dang denotes a collapse index, w₁ denotes the weight of microbial activity, and w₂ denotes the weight of pressure fluctuation. Microbial activity weight and pressure fluctuation weight meet the weight constraint conditions: w₁+w₂=1.

A karst collapse susceptibility evaluation analysis system based on analytic hierarchy process, including:
data acquisition module, configured to mark the measurement points in the karst area, collect the karst data of the measurement points, standardize the karst data, and obtain the standard karst data;
point division module, configured to perform a geomagnetic division of measurement points based on geomagnetic intensity to obtain a hole point set;
index evaluation module, configured to evaluate the biological activity of the hole point set by soil microbial data and obtain the microbial activity index; based on the atmospheric pressure, the pressure fluctuation analysis of the hole point set is carried out to obtain the pressure fluctuation index;
evaluation and construction module, configured to construct the collapse evaluation function based on the microbial activity index and pressure fluctuation index.

The present disclosure provides a karst collapse susceptibility evaluation analysis method based on analytic hierarchy process and the technical effect and advantages of the system:

Through the analysis of geomagnetic data, the present disclosure can accurately identify the distribution and morphology of underground karst pipelines, effectively extract the information of underground karst spatial structure, and avoid the possible shortcomings of traditional methods. By evaluating the biological activity of the hole point set, the flexibility of karst collapse evaluation is enhanced, so that it can maintain efficient and accurate evaluation ability in a complex karst environment, which provides a new perspective for the biological mechanism of karst development and further improves the early warning ability of karst disasters. By analyzing the pressure fluctuation of the hole point set, the influence of atmospheric pressure fluctuation on the underground hole can be quantified, which provides a new physical parameter for the risk evaluation of karst collapse and improves the comprehensiveness and accuracy of the evaluation.

### BRIEF DESCRIPTION OF THE DRAWINGS

FIG. 1 is a schematic diagram of the karst collapse susceptibility evaluation analysis method based on analytic hierarchy process.

FIG. 2 is a schematic diagram of the karst collapse susceptibility evaluation analysis system based on analytic hierarchy process.

### DETAILED DESCRIPTION OF THE EMBODIMENTS

The technical scheme in the embodiment of the present disclosure will be clearly and completely described in combination with the attached diagram of the embodiment of the present disclosure. Obviously, the described embodiment is only part of the embodiment of the present disclosure, not all of the embodiments. Based on the embodiments in the present disclosure, all other embodiments obtained by ordinary technicians in this field without making creative labor belong to the scope of protection of the present disclosure.

### Example 1

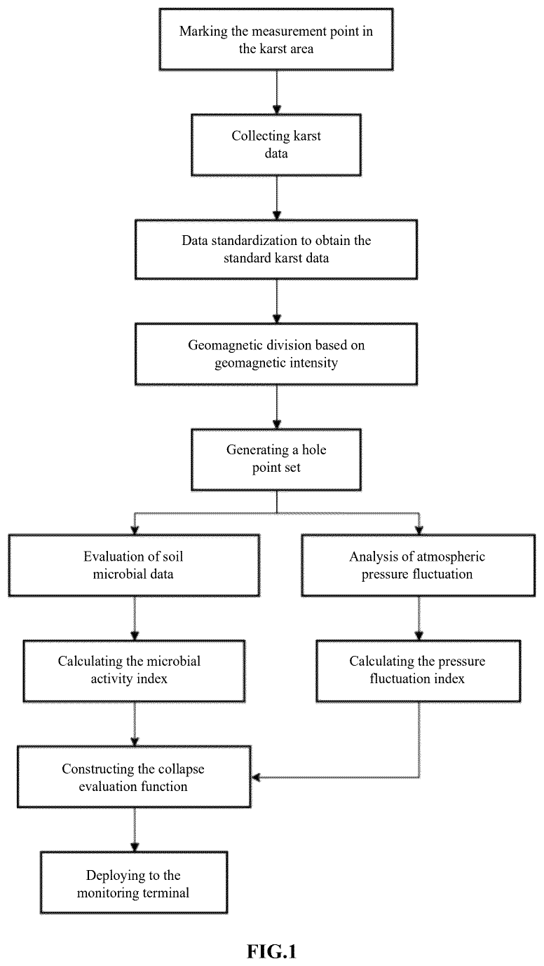

Please refer to FIG. 1, a karst collapse susceptibility evaluation analysis method based on analytic hierarchy process is described in this example, including:
S1, the measurement point in the karst area is marked, the karst data of the measurement point is collected, the karst data is standardized, and the standard karst data is obtained; the karst data include: geomagnetic intensity, soil microbial data, karst temperature, soil nitrogen and carbon content, atmospheric pressure, and point coordinates;
S2, the geomagnetic division of the measurement point based on geomagnetic intensity is performed to obtain a hole point set;
S3, the biological activity of the hole point set is evaluated by soil microbial data to obtain a microbial activity index, and a pressure fluctuation analysis of the hole point set is performed based on the atmospheric pressure to obtain the pressure fluctuation index;
S4, a collapse evaluation function is constructed based on microbial activity index and pressure fluctuation index.

The karst data include: geomagnetic intensity, soil microbial data, karst temperature, soil nitrogen and carbon content, atmospheric pressure, and point coordinates; the collection methods of rock stratum data include: preset measurement route and measurement interval. The measurement route and measurement interval are set according to the trend of the karst area or potential underground hole distribution (through geological data or remote sensing data analysis) based on the technical personnel in this field. The route can be straight or curved, depending on the geological characteristics of the karst area. The measurement points in the measurement line are marked based on the measurement interval; the initial position of the measurement line is used as the initial measurement point, and the position of each measurement interval is marked as the measurement point. Geomagnetic detector, microbial sensor, soil micro sensor, temperature sensor, and pressure sensor are set up for each measurement point. Geomagnetic detector is used to collect geomagnetic intensity, microbial sensor is used to collect soil microbial data, soil microbial data includes microbial species and species content (the number of microorganisms of the same microbial species), soil micro sensor is used to collect soil nitrogen and carbon content, soil nitrogen and carbon content is the data of nitrogen content and carbon content in soil, temperature sensor is used to collect karst temperature, pressure sensor is used to collect atmospheric pressure, and the data collection of each measurement point is collected at the same time sequence; the point coordinates are determined based on the karst area; the technicians in this field select a point in the karst area as the coordinate center point to construct a standard coordinate system, and the horizontal axis distance and vertical axis distance of each measurement point from the coordinate center point constitute the point coordinates.

In the evaluation of karst disasters, data sources are usually very diverse, including geomagnetic field data, soil microbial data, and atmospheric pressure data; the data collected by different types of sensors and monitoring equipment have problems such as different dimensions, inconsistent time scales, and accuracy differences. Sensor data may be affected by factors such as changes in the external environment and fluctuations in sensor accuracy, resulting in strong time dependence of data. For example, changes in atmospheric pressure and soil microbial communities may be seasonal or periodic, and geomagnetic field data may be affected by different external environmental disturbances. Through the data standardization of karst data, the karst data of different sources and different dimensions can be uniformly processed, which ensures that the karst data can be compared and fused under the same standard, so as to eliminate the influence of data dimension and remove the noise caused by accidental fluctuation or external environmental factors. Specifically:

For karst data, each type of data in the karst data is used as the data to be converted. The time scale is preset, and the historical mean of each data to be converted is calculated based on the time scale parameters. The recorded time point of the data to be converted is used as the cut-off point. The data to be converted at the same measurement point in the time scale before the cut-off point is selected to form a scale set, and the mean value of the data in the scale set is calculated as the historical mean. The recorded time point of the data to be converted is used as the measurement time, and the data to be converted at the same measurement time is selected to form the time data set. The mean value of the data in the time data set is used as the time mean, and the standard deviation of the data in the time data set is used as the time standard deviation. Based on the historical mean, time mean, and time standard deviation, the data to be converted are standardized. The formula for standardizing the data to be converted is:

$$Res = arc sin h ( \frac{data - μ}{σ} ) \times exp ( - \frac{\vert data - \overline{d} \vert}{τ} ) ;$$

where Res denotes the standard data, data denotes the data to be converted, μ denotes the mean value of the time, σ denotes the time standard deviation, τ denotes the time scale, d̅ denotes the historical mean, arcsinh( ) denotes an inverse hyperbolic sine function, and all standard data constitute the standard karst data. Standardization of the data to be converted incorporates the time dependence of karst data into the standardization process by introducing a time attenuation term; this method can smooth the time change trend in historical data, so as to better capture the long-term change pattern, and then remove the influence of short-term abnormal fluctuation.

The current karst collapse evaluation methods usually ignore the relationship between the morphological characteristics of the underground karst pipeline network and the geomagnetic anomaly. As a result, the distribution and changes of underground pipelines cannot be accurately identified in the actual karst collapse evaluation process, resulting in inaccurate evaluation results, and thus the occurrence of karst collapse cannot be effectively warned; the geomagnetic division of the measurement points can more accurately reflect the development of karst at different times and different depths, and then provide more accurate karst collapse risk prediction. Specifically:

Based on the measurement route, the previous measurement point of the current measurement point is selected as the difference analysis point; the finite difference method is used to analyze the geomagnetic intensity of the current measurement point by the difference analysis point, and the lateral variation factor is obtained; the finite difference method is used to analyze the geomagnetic intensity of the current measurement point by the finite difference method, and the longitudinal variation factor is obtained. The depth scale set is preset, the depth scale set is traversed, and the traversed elements are used as scale factors. The magnetic field tensor analysis is performed on each scale factor. The formula for magnetic field tensor analysis of each scale factor is as follows:

∇B=\sqrt{(BL×s)²+(BV×v)²}×exp(−φ×h); where ∇B denotes the geomagnetic depth tensor, s denotes the horizontal axis basis vector, v denotes the vertical axis basis vector, BL denotes the lateral variation factor, BV denotes the longitudinal variation factor, h denotes the scale factor, and φ denotes the attenuation coefficient, which is used to control the attenuation rate of the magnetic field with the underground depth. The geomagnetic span is preset, and the geomagnetic span includes the horizontal axis span and the longitudinal axis span. Based on the geomagnetic depth tensor, the geomagnetic anomaly evaluation of the measurement point is performed. The formula for evaluating the geomagnetic anomaly of the measurement point is

$$MAI = {\int }_{y - b}^{y + b} {\int }_{x - a}^{x + a} \vert ∇ B \vert dx dy \times ( 1 + γcos ( wt ) ) ;$$

where MAI denotes a magnetic anomaly intensity index, a denotes a horizontal axis span, b denotes a vertical axis span, x denotes a horizontal axis value of the point coordinate, y denotes a vertical axis value of the point coordinate, dx and dy denote integral operations, γ denotes a period adjustment coefficient, it controls the amplitude of the periodic variation, which denotes the periodic variation of the geomagnetic field with time, w denotes an angular frequency parameter, which is used to simulate the fluctuation of the direction of the geomagnetic intensity with time, and t denotes a time scale. The spline analysis method is used to construct the magnetic anomaly fluctuation curve with the scale factor and the corresponding magnetic anomaly intensity index. The maximum point and the minimum point of the extreme value of the magnetic anomaly fluctuation curve are recorded. The difference between the maximum point and the minimum point of the extreme value is used as the hole evaluation index, and the hole evaluation threshold is preset. The measurement points with the hole evaluation index greater than or equal to the hole evaluation threshold are marked as the hole points. The scale factor with the small value of the scale factor corresponding to the maximum point and the minimum point is the start point of the hole, and the other is the end point of the hole. The data of the start point and the end point of the hole are merged into the hole point, and all the hole points constitute the hole point set.

The development of karst is also affected by the structure of the soil microbial community; microorganisms can change the formation environment of karst through chemical reactions and mineral degradation. For example, sulfate-reducing bacteria and iron-reducing bacteria produce acidic substances through their metabolic processes, such as sulfuric acid and hydrogen ions. These acidic substances can react with minerals in rocks, promote dissolution, and accelerate the formation and expansion of underground karst, especially in limestone areas; the formation of acidic substances will lead to the dissolution of calcium carbonate and the formation of karst cavities and pipelines. The existing evaluation methods fail to take into account the impact of microbial communities, ignoring the role of this biological factor in karst development; the evaluation is not comprehensive enough, and the risk of karst collapse in some areas is underestimated. By evaluating the biological activity of the hole point set, the contribution of microbial activities to karst development can be better revealed, and the accuracy of risk evaluation can be improved. Specifically:

The statistical analysis method is used to analyze the soil microbial data of all measurement points, and the microbial category table is obtained. The microbial category table contains the microbial species and the corresponding total number of species; the number of species of each microbial species in the hole point is divided by the total number of species of the corresponding microbial species in the microbial category table as the species richness. Based on the species richness, the biodiversity of each measurement point is evaluated, the formula for biodiversity evaluation at each measurement point is:

$$Act = - sin \frac{π S}{{S}_{max}} \sum ( {E}_{i} \times ln {E}_{i} ) \times exp ( - δ T ) ;$$

where Act denotes a biodiversity index, π denotes a circumference rate, S denotes the microbial species, Sₘₐₓ denotes the total number of microbial species in the microbial category table, Pᵢ denotes a species richness of the i-th microbial species in the hole point, δ denotes a temperature adjustment coefficient, which is used to control the influence of temperature on microorganisms, it is set by the technical personnel in this field based on the actual situation, T denotes a karst temperature. The maximum value of the biodiversity index is recorded as the maximum activity index of the area. The microbial activity of the hole point is evaluated based on the maximum activity index of the area. The formula for evaluating the microbial activity of the hole point is

$$BAI = \frac{Act}{Mliv} \times θ ln ( 1 + \frac{N}{C} ) ;$$

where BAI denotes the microbial activity index, Mliv denotes the maximum activity index, θ denotes the environmental regulation coefficient, which is used to control the impact of environmental nutrients on microbial activity, N denotes the soil nitrogen content, and C denotes the soil carbon content.

The fluctuation of atmospheric pressure affects the stability of underground cavities, especially under seasonal or sudden climate change, pressure fluctuations will have different degrees of impact on underground structures. The current karst collapse evaluation methods lack the analysis of the coupling mechanism of atmospheric pressure fluctuations, which increases the evaluation error, and then leads to the failure of effective early warning before disasters occur. Through the analysis of pressure fluctuations in the hole point set, the specific impact of atmospheric pressure fluctuations on the risk of karst collapse can be quantitatively described. It provides a unified quantitative standard for cavities in different areas and different depths, thus providing strong data support for the prediction of karst disasters, specifically:

The hole point in the hole point set is used as the regional center, and the distance scale is preset. The distance scale is used as the regional radius, the regional center is used as the center of the circle, and the regional radius is used as the circle radius to draw the circle to obtain the regional circle. The measurement points contained in the regional circle are used as the pressure evaluation points, and the pressure evaluation points and the pressure center are used as the fluctuation analysis points. For each fluctuation analysis point, the fluctuation analysis point is used as the pressure center to draw the cross line, and the four areas divided by the cross line are used as the selection domain. The distance measurement formula is used to calculate the distance between other fluctuation analysis points and the center of the cross line as the evaluation distance, the fluctuation analysis point with the smallest evaluation distance is selected as the pressure boundary point in each selection domain. The pressure boundary points in the diagonal area are taken as a boundary group, and the fluctuation analysis points in the center of the cross line are taken as the difference center. The central difference algorithm is used to calculate the pressure fluctuation gradient of each group of boundary groups, the mean value of the pressure fluctuation gradient is used as the fluctuation factor, and the mean value of the fluctuation factor of all the fluctuation analysis points is calculated as the pressure propagation operator. The diagonal area is determined based on quadrant division. The four areas of the two-dimensional coordinate system represent four quadrants, the diagonal areas are the first quadrant and the third quadrant, the second quadrant and the fourth quadrant, respectively; the pressure fluctuation of the hole point is evaluated based on the pressure propagation operator. The formula for evaluating the pressure fluctuation of the hole point is:

$$PI = {\int }_{low}^{hig} ( SZ \times tan h ( \frac{Δ P}{{P}_{0}} ) ) \times exp ( - ε H ) dH ;$$

where PI denotes the pressure fluctuation index, SZ denotes a pressure fluctuation factor, it is set by the technical personnel in this field based on the actual situation, P₀ denotes the standard atmospheric pressure, ΔP denotes the difference between the atmospheric pressure and the standard atmospheric pressure, ε denotes the fluctuation attenuation coefficient, which is used to simulate the attenuation of pressure fluctuation, it is set by the technical personnel in this field based on the actual situation, low denotes the start point of the hole, hig denotes the end point of the hole, and H denotes the depth of the hole.

Assuming that the atmospheric pressure of a set of boundary groups is P₁ and P₂ respectively, the point coordinates are (x₁, y₁) and (x₂, y₂) respectively, the atmospheric pressure of the difference center is P_{cen}, and the point coordinates are (x_{cen}, y_{cen}); the calculation the central is formula of difference algorithm

$$BTD = \sqrt{{( \frac{\vert {P}_{1} + {P}_{2} - 2 {P}_{cen} \vert}{{( {x}_{1} - {x}_{2} )}^{2}} )}^{2} + {( \frac{\vert {P}_{1} + {P}_{2} - 2 {P}_{cen} \vert}{{( {y}_{1} - {y}_{2} )}^{2}} )}^{2}} ;$$

where BTD denotes the pressure fluctuation gradient.

Based on the microbial activity index and the pressure fluctuation index, the collapse evaluation function is constructed, the formula of the collapse evaluation function is Dang=w₁×BAI+w₂×PI; w₁ denotes the weight of microbial activity, and w₂ denotes the weight of pressure fluctuation. Microbial activity weight and pressure fluctuation weight meet the weight constraint conditions: w₁+w₂=1; when the collapse index is larger, the point is easier to collapse; the weight of microbial activity and the weight of pressure fluctuation are set by the technicians in this field based on the actual situation. The value of microbial activity weight should be increased for the area with high soil nitrogen and carbon content, and the value of pressure fluctuation weight should be increased for the area with large atmospheric pressure fluctuation. The collapse evaluation function is deployed to the monitoring terminal. When the collapse index is greater than or equal to the preset collapse threshold, the monitoring terminal will alarm.

Through the analysis of geomagnetic data, this embodiment can accurately identify the distribution and morphology of underground karst pipelines, effectively extract the information of underground karst spatial structure, and avoid the possible shortcomings of traditional methods. By evaluating the biological activity of the hole point set, the flexibility of karst collapse evaluation is enhanced, so that it can maintain efficient and accurate evaluation ability in a complex karst environment, which provides a new perspective for the biological mechanism of karst development and further improves the early warning ability of karst disasters. By analyzing the pressure fluctuation of the hole point set, the influence of atmospheric pressure fluctuation on the underground hole can be quantified, which provides a new physical parameter for the risk evaluation of karst collapse and improves the comprehensiveness and accuracy of the evaluation.

### Example 2

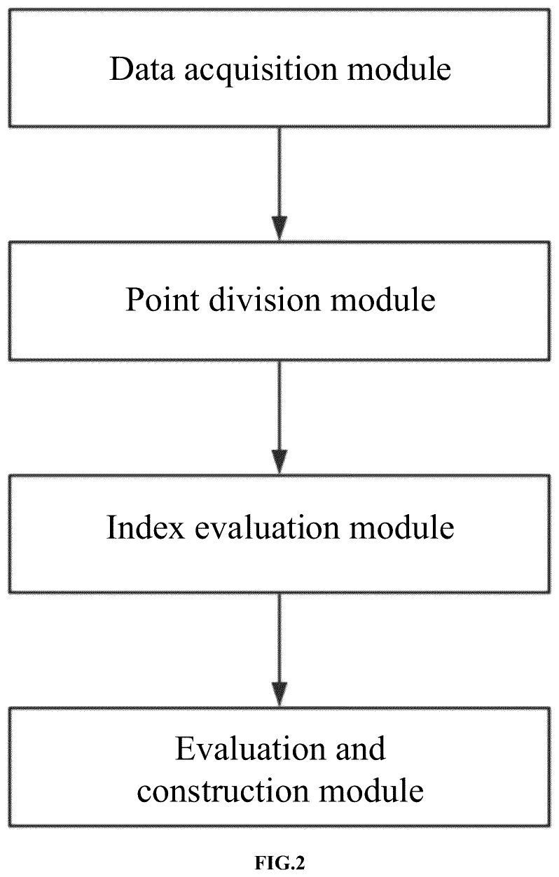

As shown in FIG. 2. The undetailed description of this example can be referred to the description of Example 1. A karst collapse susceptibility evaluation analysis system based on analytic hierarchy process is provided, including:
data acquisition module, configured to mark the measurement points in the karst area, collect the karst data of the measurement points, standardize the karst data, and obtain the standard karst data;
point division module, configured to perform a geomagnetic division of measurement points based on geomagnetic intensity to obtain a hole point set;
index evaluation module, configured to evaluate the biological activity of the hole point set by soil microbial data and obtain the microbial activity index; based on the atmospheric pressure, the pressure fluctuation analysis of the hole point set is carried out to obtain the pressure fluctuation index;
evaluation and construction module, configured to construct the collapse evaluation function based on the microbial activity index and pressure fluctuation index;
each module is connected by wired and/or wireless to realize data transmission between modules.

### Example 3

This embodiment openly provides an electronic device, including a memory, a processor, and a computer program that is stored on the memory and can be run on the processor. When the processor executes the computer program, it realizes the operation mode of the karst collapse susceptibility evaluation analysis method based on analytic hierarchy process.

Because the electronic equipment introduced in this example is an electronic equipment used in the karst collapse susceptibility evaluation analysis method based on analytic hierarchy process in the example of this application, so according to the karst collapse susceptibility evaluation analysis method based on analytic hierarchy process introduced in the example of this application, the technical personnel in this field can understand the specific implementation methods of the electronic equipment of this example and its various forms of change. Therefore, how to realize the method in the example of this application is no longer introduced in detail. As long as the technical personnel in this field implement the electronic equipment adopted by the karst collapse susceptibility evaluation analysis method based on analytic hierarchy process in the example of this application, all belong to the scope of protection intended by this application.

The above formulas are calculated by taking the numerical value and removing the dimension of quantity, the formula is a formula of the recent real situation obtained by collecting a large amount of data for software simulation. The preset parameters and threshold selection in the formula are set by the technicians in this field according to the actual situation.

The above examples are only preferred methods of the present disclosure, the protection scope of the present disclosure is not limited to the above implementation examples. All technical schemes belonging to the idea of the present disclosure belong to the protection scope of the present disclosure. It should be pointed out that for ordinary technicians in this technical field, the improvements and embellishments without deviating from the principle of the present disclosure should also be regarded as the protection scope of the present disclosure.

What is claimed is:

1. A karst collapse susceptibility evaluation analysis method based on an analytic hierarchy process, comprising:
S1, marking a measurement point in a karst area, collecting karst data of the measurement point, standardizing the karst data, and obtaining the standard karst data; wherein the karst data include: geomagnetic intensity, soil microbial data, karst temperature, soil nitrogen and carbon content, atmospheric pressure, and point coordinates;
S2, performing a geomagnetic division of the measurement point based on geomagnetic intensity to obtain a hole point set;
S3, evaluating a biological activity of the hole point set by soil microbial data to obtain a microbial activity index, and performing a pressure fluctuation analysis of the hole point set based on the atmospheric pressure to obtain the pressure fluctuation index;
S4, constructing a collapse evaluation function based on the microbial activity index and the pressure fluctuation index;
wherein the method for obtaining the microbial activity index comprises:
using a statistical analysis method to analyze soil microbial data of all measurement points, and obtaining a microbial category table, wherein the microbial category table comprises the microbial species and a corresponding total number of species;
dividing a count of species of each microbial species in a hole point by the total number of species of the corresponding microbial species in the microbial category table as a species richness;
based on the species richness, evaluating a biodiversity of each measurement point to obtain a biodiversity index, and recording a maximum value of the biodiversity index as a maximum activity index of the area;
based on the maximum activity index of the area, evaluating a microbial activity of the hole point to obtain the microbial activity index;
wherein obtaining the pressure fluctuation index comprises:
using a hole point in the hole point set as a regional center, and presetting a distance scale;
using the distance scale as a regional radius, the regional center as a center of a circle, and the regional radius as the circle radius to draw a circle to obtain a regional circle;
using measurement points contained in the regional circle as pressure evaluation points, and the pressure evaluation points and pressure centers as fluctuation analysis points;
for each fluctuation analysis point, using the fluctuation analysis point as a pressure center to draw a cross line, and using the four areas divided by the cross line as selection domains;
using a distance measurement formula to calculate a distance between other fluctuation analysis points and a center of the cross line as an evaluation distance;
selecting a fluctuation analysis point with a smallest evaluation distance in each selection domain as a pressure boundary point;
using the pressure boundary points in the diagonal area as a boundary group, and using the fluctuation analysis point in the center of the cross line as a difference center;
using a central difference algorithm to calculate a pressure fluctuation gradient of each group of boundary groups;
using a mean value of the pressure fluctuation gradient as a fluctuation factor, and calculating a mean value of the fluctuation factor of all fluctuation analysis points as a pressure propagation operator;
based on the pressure propagation operator, obtaining a pressure fluctuation index by evaluating the pressure fluctuation of the hole point.

2. The karst collapse susceptibility evaluation analysis method based on analytic hierarchy process according to claim 1, wherein the collection method of karst data comprises:
presetting a measurement route and a measurement interval, and marking the measurement points in a measurement line based on the measurement interval;
using an initial position of the measurement line as an initial measurement point;
starting from the initial measurement point, marking a position of each measurement interval as the measurement point, and setting a geomagnetic detector, a microbial sensor, a soil micro sensor, a temperature sensor and a pressure sensor for each measurement point; and
acquiring data for each measurement point in the same time series; determining the point coordinates based on the karst area, selecting a point in the karst area as a coordinate center point to construct a standard coordinate system;
wherein a horizontal axis distance and a vertical axis distance of each measurement point from the coordinate center point constitute the point coordinates.

3. The karst collapse susceptibility evaluation analysis method based on analytic hierarchy process according to claim 2, wherein the method of geomagnetic division of the measurement point comprises:
for karst data, using each type of data in the karst data as data to be converted; presetting a time scale, and calculating a historical mean of each data to be converted based on time scale parameters;
using a recorded time point of the data to be converted as a cut-off point;
selecting a data to be converted at the same measurement point in the time scale before the cut-off point to form a scale set, wherein a mean value of the data in the scale set is calculated as a historical mean;
using a recorded time point of the data to be converted as a measurement time, and selecting the data to be converted at the same measurement time to form a time data set;
using a mean value of the data in the time data set as a mean time, and using a standard deviation of the data in the time data set as a time standard deviation;
based on the historical mean, time mean and time standard deviation, standardizing the data to be converted, the formula for standardizing the data to be converted is:
$$Res = arcsin h ( \frac{data - μ}{σ} ) \times exp ( - \frac{\vert data - \overline{d} \vert}{τ} ) ;$$
where Res denotes the standard data, data denotes the data to be converted, μ denotes the mean value of the time, σ denotes the time standard deviation, τ denotes the time scale, d̅ denotes the historical mean, arcsinh( ) denotes an inverse hyperbolic sine function, and all standard data constitute the standard karst data.

4. The karst collapse susceptibility evaluation analysis method based on analytic hierarchy process according to claim 3, wherein the method of geomagnetic division of the measurement points comprises:
based on the measurement route, selecting a previous measurement point of the current measurement point as a differential analysis point;
using a finite difference method to analyze a geomagnetic intensity of the current measurement point by the differential analysis point, and obtaining a lateral variation factor;
using the finite difference method to analyze the geomagnetic intensity of the current measurement point by the finite difference method, and obtaining a longitudinal variation factor;
presetting a depth scale set, traversing the depth scale set, and using the traversed element as a scale factor;
performing a magnetic field tensor analysis of each scale factor to obtain a geomagnetic depth tensor;
presetting a geomagnetic span, wherein the geomagnetic span comprises a horizontal axis span and a vertical axis span;
performing a geomagnetic anomaly evaluation of the measurement points based on the geomagnetic depth tensor to obtain a magnetic anomaly intensity index;
using a spline analysis method to construct a magnetic anomaly fluctuation curve with a scale factor and a corresponding magnetic anomaly intensity index, and recording a maximum point and a minimum point of an extreme value of the magnetic anomaly fluctuation curve;
using a difference between the maximum point and the minimum point of the extreme value as a hole evaluation index, and presetting a hole evaluation threshold;
marking the measurement points with the hole evaluation index as greater than or equal to the hole evaluation threshold as the hole points;
wherein the scale factor with the smallest value of the scale factor corresponds to the maximum point and wherein a minimum point is the start point of the hole, and the other is an end point of the hole;
merging the data of the start point and the end point of the hole into the hole point, wherein all the hole points constitute the hole point set.

5. The karst collapse susceptibility evaluation analysis method based on analytic hierarchy process according to claim 4, wherein the formula for evaluating the geomagnetic anomaly of the measurement point is:
$$MAI = {\int }_{y - b}^{y + b} {\int }_{x - a}^{x + a} \vert ∇ B \vert dx dy \times ( 1 + γcos ( wt ) ) ;$$
where MAI denotes a magnetic anomaly intensity index, a denotes a horizontal axis span, b denotes a vertical axis span, x denotes a horizontal axis value of the point coordinate, y denotes a vertical axis value of the point coordinate, dx and dy denote integral operations, γ denotes a period adjustment coefficient, w denotes an angular frequency parameter, and t denotes a time scale.

6. The karst collapse susceptibility evaluation analysis method based on analytic hierarchy process according to claim 5, wherein the formula for evaluating the microbial activity of the hole points is:
$$BAI = \frac{Act}{Mliv} \times θ ln ( 1 + \frac{N}{C} ) ;$$
where BAI denotes a microbial activity index, Mliv denotes a maximum activity index, θ denotes an environmental regulation coefficient, N denotes a soil nitrogen content, and C denotes a soil carbon content.

7. The karst collapse susceptibility evaluation analysis method based on analytic hierarchy process according to claim 6, wherein the formula for biodiversity evaluation at each measurement point is as follows:
$$Act = - sin \frac{π S}{{S}_{max}} \sum ( {E}_{i} \times ln {E}_{i} ) \times exp ( - δ T ) ;$$
where Act denotes a biodiversity index, π denotes a circumference rate, S denotes the microbial species, Sₘₐₓ denotes the total number of microbial species in the microbial category table, Pᵢ denotes a species richness of the i-th microbial species in the hole point, δ denotes a temperature adjustment coefficient, and T denotes a karst temperature.

8. The karst collapse susceptibility evaluation analysis method based on analytic hierarchy process according to claim 7, wherein the formula for evaluating the pressure fluctuation of the hole point is:
$$PI = {\int }_{low}^{hig} ( SZ \times tan h ( \frac{Δ P}{{P}_{0}} ) ) \times exp ( - ε H ) dH ;$$
where PI denotes a pressure fluctuation index, SZ denotes a pressure fluctuation factor, P₀ denotes a standard atmospheric pressure, ΔP denotes a difference between the atmospheric pressure and the standard atmospheric pressure, ε denotes a fluctuation attenuation coefficient, low denotes a start point of the hole, hig denotes the end point of the hole, and H denotes a depth of the hole.

9. The karst collapse susceptibility evaluation analysis method based on analytic hierarchy process according to claim 8, wherein the formula of the collapse evaluation function is as follows:
Dang=w₁×BAI+w₂× PI; Dang denotes a collapse index, w₁ denotes the weight of microbial activity, and w₂ denotes the weight of pressure fluctuation; microbial activity weight and pressure fluctuation weight meet the weight constraint conditions: w₁+w₂=1.

10. A karst collapse susceptibility evaluation analysis system based on analytic hierarchy process, the system is used to implement the karst collapse susceptibility evaluation analysis method based on analytic hierarchy process according to claim 1, wherein comprising:
data acquisition module, configured to mark the measurement points in the karst area, collect the karst data of the measurement points, standardize the karst data, and obtain the standard karst data;
point division module, configured to perform a geomagnetic division of measurement points based on geomagnetic intensity to obtain a hole point set;
index evaluation module, configured to evaluate the biological activity of the hole point set by soil microbial data and obtain the microbial activity index; based on the atmospheric pressure, the pressure fluctuation analysis of the hole point set is carried out to obtain the pressure fluctuation index;
evaluation and construction module, configured to construct the collapse evaluation function based on the microbial activity index and pressure fluctuation index.
